(19) United States
(12) Patent Application Publication
(10) Pub. No.: US 2025/0364300 A1
(43) Pub. Date: Nov. 27, 2025

(54) SUBSTRATE HOLDING DEVICE AND BONDING SYSTEM

(71) Applicant: Tokyo Electron Limited, Tokyo (JP)

(72) Inventor: Hironori HONDA, Koshi City (JP)

(73) Assignee: Tokyo Electron Limited, Tokyo (JP)

(21) Appl. No.: 19/212,688

(22) Filed: May 20, 2025

(30) Foreign Application Priority Data
May 21, 2024 (JP) 2024-082692

(51) Int. Cl. H01L 21/683; H01L 21/67

(52) U.S. Cl. CPC H01L 21/6838; H01L 21/67092

(57) ABSTRACT

A substrate holding device includes a main body, a flow passage and a suction hole. The main body has a circular attraction surface facing a circular plate-shaped substrate. The flow passage is formed between a pair of ribs extending from a central region of the attraction surface to a peripheral region of the attraction surface. The suction hole is located in the flow passage on a central region side of the attraction surface. Air flow is formed along the flow passage, heading from the peripheral region toward the suction hole as the pair of ribs come close to or into contact with the substrate.

### CROSS-REFERENCE TO RELATED APPLICATION

This application claims priority under 35 U.S.C. § 119 (a) to Japanese Patent Application No. 2024-082692 filed on May 21, 2024, the entire disclosure of which is incorporated herein by reference.

### TECHNICAL FIELD

The various aspects and embodiments described herein pertain generally to a substrate holding device and a bonding system.

### BACKGROUND

Patent Document 1 discloses a bonding apparatus that bonds an upper substrate held by an upper chuck and a lower substrate held by a lower chuck that is configured to be movable horizontally and vertically relative to the upper chuck (see Patent Document 1).
Patent Document 1: Japanese Patent-Laid open Publication No. 2015-095579

### SUMMARY

In an exemplary embodiment, a substrate holding device includes a main body, a flow passage and a suction hole. The main body has a circular attraction surface facing a circular plate-shaped substrate. The flow passage is formed between a pair of ribs extending from a central region of the attraction surface to a peripheral region of the attraction surface. The suction hole is located in the flow passage on a central region side of the attraction surface. An air flow is formed along the flow passage, heading from the peripheral region toward the suction hole as the pair of ribs come close to or into contact with the substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating a configuration of a bonding system according to an exemplary embodiment;

FIG. 2 is a schematic side view illustrating the configuration of the bonding system according to the exemplary embodiment;

FIG. 3 is a schematic side view of an upper wafer and a lower wafer according to the exemplary embodiment;

FIG. 4 is a schematic cross sectional view illustrating a configuration of a surface modifying apparatus according to the exemplary embodiment;

FIG. 5 is a schematic plan view illustrating a configuration of a bonding apparatus according to the exemplary embodiment;

FIG. 6 is a schematic side view illustrating the configuration of the bonding apparatus according to the exemplary embodiment;

FIG. 7 is a schematic side view illustrating a configuration of an upper chuck and a lower chuck of the bonding apparatus according to the exemplary embodiment;

FIG. 8 is a flowchart showing a part of a processing sequence of a processing performed by the bonding system according to the exemplary embodiment;

FIG. 9 is a plan view illustrating an example configuration of the upper chuck according to the exemplary embodiment;

FIG. 10 is an enlarged plan view illustrating the example configuration of the upper chuck according to the exemplary embodiment;

FIG. 11 is a cross sectional view taken along a line B-B of FIG. 10 in a direction indicated by the arrows;

FIG. 12 is a diagram showing a simulation result of an attracting force in the upper chuck according to the exemplary embodiment;

FIG. 13 is a plan view illustrating another example configuration of the upper chuck according to the exemplary embodiment;

FIG. 14 is an enlarged plan view illustrating an example configuration of the upper chuck according to a first modification example of the exemplary embodiment;

FIG. 15 is a cross sectional view illustrating an example configuration of the upper chuck according to a second modification example of the exemplary embodiment;

FIG. 16 is an enlarged plan view illustrating an example configuration of the upper chuck according to a third modification example of the exemplary embodiment;

FIG. 17 is a diagram showing a simulation result of an attracting force in the upper chuck according to the third modification example of the exemplary embodiment;

FIG. 18 is an enlarged plan view illustrating an example configuration of an upper chuck according to a fourth modification example of the exemplary embodiment;

FIG. 19 is a diagram showing a simulation result of an attracting force in the upper chuck according to the fourth modification example of the exemplary embodiment;

FIG. 20 is an enlarged plan view illustrating an example configuration of the upper chuck according to a fifth modification example of the exemplary embodiment; and

FIG. 21 is an enlarged plan view illustrating an example configuration of the upper chuck according to a sixth modification example of the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate holding device and a bonding system according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, there is known a bonding apparatus that bonds an upper substrate held by an upper chuck and a lower substrate held by a lower chuck that is configured to be movable horizontally and vertically relative to the upper chuck.

In the prior art, when the upper substrate is held by the upper chuck, if the upper substrate is warped so a peripheral region of this warped upper substrate is significantly spaced apart from the upper chuck, an attracting force in this peripheral region does not rise to a required level, raising a risk that the upper substrate may not be stably held.

In this regard, there is a demand for a technique capable of overcoming the aforementioned problem and holding the warped substrate stably.

### <Configuration of Bonding System>

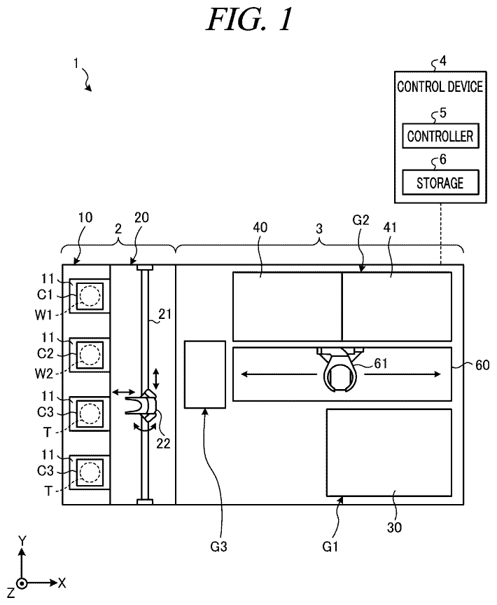

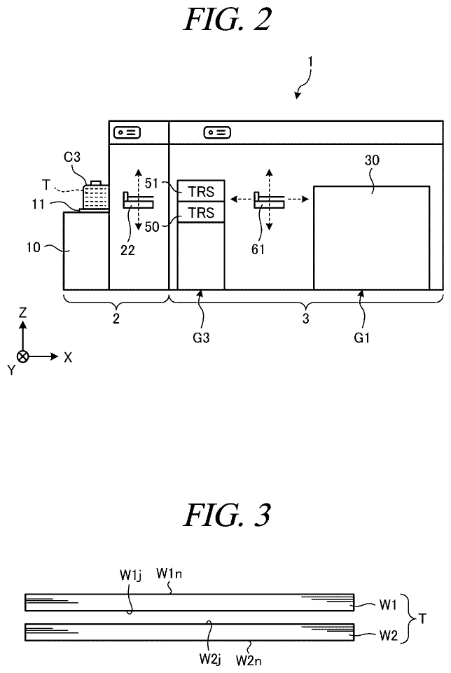

First, a configuration of a bonding system 1 according to an exemplary embodiment will be explained with reference to FIG. 1 to FIG. 3. FIG. 1 is a schematic plan view showing the configuration of the bonding system 1 according to the exemplary embodiment, and FIG. 2 is a schematic side view of the same. FIG. 3 is a schematic side view of an upper wafer and a lower wafer according to the exemplary embodiment. In the various drawings to be referred to below, in order to make the following explanation easier to understand, an orthogonal coordinate system in which the Z-axis direction is defined as a vertically upward direction may be used.

The bonding system 1 shown in FIG. 1 bonds a first substrate W1 and a second substrate W2 to form a combined substrate T.

The first substrate W1 is a semiconductor substrate such as a silicon wafer or a compound semiconductor wafer on which a multiple number of electronic circuits are formed. The second substrate W2 is a bare wafer on which no electronic circuit is formed. The first substrate W1 and the second substrate W2 have substantially the same diameter. In the present disclosure, the second substrate W2 may also have an electronic circuit formed thereon.

In the following, the first substrate W1 will be referred to as “upper wafer W1,” the second substrate W2 will be referred to as “lower wafer W2,” and the combined substrate T will be referred to as “combined wafer T.” That is, the upper wafer W1 is an example of a first substrate, and the lower wafer W2 is an example of a second substrate. The upper wafer W1 is also an example of a substrate. In addition, the upper wafer W1 and the lower wafer W2 may sometimes be collectively referred to as “wafer W.”

In addition, hereinafter, as illustrated in FIG. 3, among plate surfaces of the upper wafer W1, the plate surface to be bonded to the lower wafer W2 will be referred to as “bonding surface W1j,” and the plate surface opposite the bonding surface W1j will be referred to as “non-bonding surface Win.” Likewise, among plate surfaces of the lower wafer W2, the plate surface to be bonded to the upper wafer W1 will be referred to as “bonding surface W2j,” and the plate surface opposite the bonding surface W2j will be referred to as “non-bonding surface W2n.”

As shown in FIG. 1, the bonding system 1 is equipped with a carry-in/out station 2 and a processing station 3. The carry-in/out station 2 and the processing station 3 are arranged in the order of the carry-in/out station 2 and the processing station 3 along the positive X-axis direction. Also, the carry-in/out station 2 and the processing station 3 are connected as a single structure.

The carry-in/out station 2 includes a placement table 10 and a transfer section 20. The placement table 10 is equipped with a multiple number of placement plates 11. Provided on the respective placement plates 11 are cassettes C1, C2 and C3 each of which accommodates a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. In addition to the cassettes C1, C2, and C3, a cassette for collecting a defective substrate or the like may also be disposed on the placement plate 11.

The processing station 3 has a plurality of processing blocks equipped with various types of devices, for example, three processing blocks G1, G2 and G3. For example, the first processing block G1 is provided on the front side (negative Y-axis side of FIG. 1) of the processing station 3, and the second processing block G2 is provided on the rear side (positive Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2 with plasma of a processing gas. The surface modifying apparatus 30 cuts a SiO₂ bond in the bonding surfaces W1j and W2j of the upper and lower wafers W1 and W2 to form a single bond of SiO, thus modifying the bonding surfaces W1j and W2j so that they can be easily hydrophilized afterwards.

For example, in the surface modifying apparatus 30, a preset processing gas is excited into plasma under a decompressed atmosphere to be ionized. Then, ions of elements contained in this processing gas are irradiated to the bonding surfaces W1j and W2j of the upper wafer and lower wafers W1 and W2, whereby the bonding surfaces W1j and W2j are plasma-processed and modified. Details of this surface modifying apparatus 30 will be described later.

Further, a surface hydrophilizing apparatus 40 and a bonding apparatus 41 are located in the second processing block G2. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

The bonding apparatus 41 is configured to bond the upper wafer W1 and the lower wafer W2. Details of this bonding apparatus 41 will be discussed later.

In the third processing block G3, transition (TRS) devices 50 and 51 for the upper wafer W1, the lower wafer W2, and the combined wafer T are provided in two stages in this order from the bottom, as illustrated in FIG. 2.

Further, as shown in FIG. 1, a transfer area 60 is formed in a region surrounded by the first processing block G1, the second processing block G2, and the third processing block G3. A transfer device 61 is disposed in the transfer area 60. The transfer device 61 has a transfer arm configured to be movable horizontally and vertically and pivotable around a vertical axis, for example.

This transfer device 61 is moved within the transfer area 60 to transfer the upper wafer W1, the lower wafer W2, and the combined wafer T to devices within the first processing block G1, the second processing block G2, and the third processing block G3 adjacent to the transfer area 60.

Further, the bonding system 1 is equipped with a control device 4. The control device 4 is configured to control an operation of the bonding system 1. This control device 4 is, for example, a computer, and has a controller 5 and a storage 6. The storage 6 stores a program for controlling various processes such as a bonding process. The controller 5 controls the operation of the bonding system 1 by reading and executing the program stored in the storage 6. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

In addition, such a program may have been recorded on a computer-readable recording medium, and may be installed from the recording medium into the storage 6 of the control device 4. The computer-readable recording medium may be, by way of non-limiting example, a hard disk (HD), a flexible disk (FD), a compact disk (CD), a magnet optical disk (MO), a memory card, or the like.

### <Configuration of the Surface Modifying Apparatus>

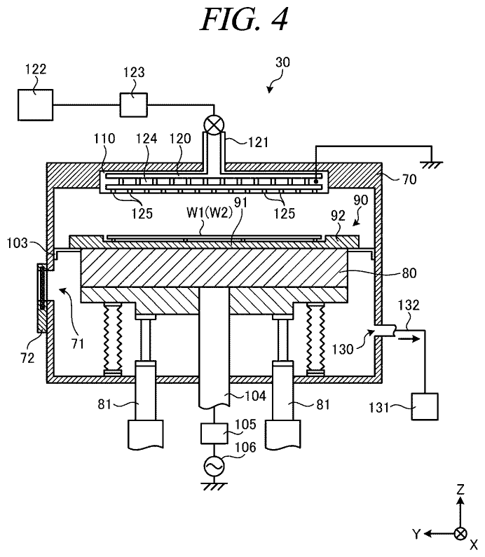

Now, a configuration of the surface modifying apparatus 30 will be explained with reference to FIG. 4. FIG. 4 is a schematic cross sectional view illustrating the configuration of the surface modifying apparatus 30.

As depicted in FIG. 4, the surface modifying apparatus 30 has a hermetically sealable processing vessel 70. A carry-in/out opening 71 for the upper wafer W1 or the lower wafer W2 is formed in a side surface of the processing vessel 70 facing the transfer area 60 (see FIG. 1), and a gate valve 72 is provided at this carry-in/out opening 71.

A stage 80 is located in the processing vessel 70. The stage 80 is, for example, a lower electrode, and is made of a conductive material such as, but not limited to, aluminum. A plurality of drivers 81 each equipped with, for example, a motor is provided below the stage 80. The divers 81 are configured to move the stage 80 up and down.

Provided between the stage 80 and an inner wall of the processing vessel 70 is an exhaust ring 103 provided with multiple baffle holes. The exhaust ring 103 allows an atmosphere inside the processing vessel 70 to be uniformly exhausted from the processing vessel 70.

A power feed rod 104 made of a conductor is connected to a bottom surface of the stage 80. This power feed rod 104 is connected to a first high frequency power supply 106 via a matching device 105 implemented by, for example, a blocking capacitor. During a plasma processing, a preset high frequency voltage is applied to the stage 80 from the first high frequency power supply 106.

An upper electrode 110 is disposed in the processing vessel 70. A top surface of the stage 80 and a bottom surface of the upper electrode 110 are positioned parallel to each other with a certain distance therebetween. The distance between the top surface of the stage 80 and the bottom surface of the upper electrode 110 is adjusted by the drivers 81.

The upper electrode 110 is grounded and connected to the ground potential. Since the upper electrode 110 is grounded in this manner, damage to the bottom surface of the upper electrode 110 can be suppressed during the plasma processing.

In this way, as the high frequency voltage is applied from the first high frequency power supply 106 to the stage 80 serving as the lower electrode, plasma is formed in the processing vessel 70.

In the exemplary embodiment, the stage 80, the power feed rod 104, the matching device 105, the first high frequency power supply 106, and the upper electrode 110 are an example of a plasma forming mechanism that forms plasma of a processing gas in the processing vessel 70. The first high frequency power supply 106 is controlled by the controller 5 (see FIG. 1) of the control device 4 (see FIG. 1) described above.

A hollow portion 120 is formed inside the upper electrode 110. A gas supply line 121 is connected to the hollow portion 120. The gas supply line 121 is connected to a gas source 122 that stores therein a processing gas and a charge neutralization gas. Also, the gas supply line 121 is provided with a supply equipment group 123 including a flow rate controller and a valve for controlling the flow of the processing gas and the charge neutralization gas.

The processing gas and the charge neutralization gas supplied from the gas source 122 are introduced into the hollow portion 120 of the upper electrode 110 via the gas supply line 121 with their flow rates controlled by the supply equipment group 123. The processing gas may be, by way of non-limiting example, an oxygen gas, a nitrogen gas, an argon gas, etc. The charge neutralization gas may be, by way of non-limiting example, an inert gas such as a nitrogen gas or an argon gas.

A baffle plate 124 is provided in the hollow portion 120 to promote uniform diffusion of the processing gas and the charge neutralization gas. The baffle plate 124 is provided with a multiple number of small holes. Also, a multiple number of gas discharge openings 125 are formed in the bottom surface of the upper electrode 110 to eject the processing gas and the charge neutralization gas from the hollow portion 120 into the processing vessel 70.

The processing vessel 70 is provided with a suction port 130. The suction port 130 is connected to a suction line 132 that communicates with a vacuum pump 131 which is configured to reduce the pressure of the atmosphere inside the processing vessel 70 to a required vacuum level.

The top surface of the stage 80, i.e., the surface facing the upper electrode 110, is a horizontal surface that is circular when viewed from the top and has a larger diameter than the upper wafer W1 and the lower wafer W2. A stage cover 90 is placed on the top surface of the stage 80, and the upper wafer W1 or the lower wafer W2 is placed on a placement portion 91 of the stage cover 90.

### <Configuration of Bonding Apparatus>

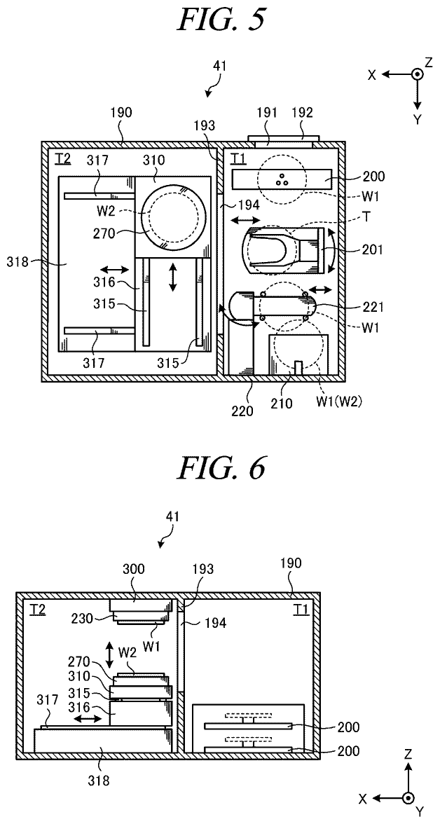

Now, a configuration of the bonding apparatus 41 will be explained with reference to FIG. 5 and FIG. 6. FIG. 5 is a schematic plan view showing the configuration of the bonding apparatus 41 according to the exemplary embodiment, and FIG. 6 is a schematic side view showing the configuration of the bonding apparatus 41 according to the exemplary embodiment.

As illustrated in FIG. 5, the bonding apparatus 41 has a hermetically sealable processing vessel 190. A carry-in/out opening 191 for the upper wafer W1, the lower wafer W2, and the combined wafer T is formed in a side surface of the processing vessel 190 facing the transfer area 60, and an opening/closing shutter 192 is provided at the carry-in/out opening 191.

The inside of the processing vessel 190 is divided into a transfer area T1 and a processing area T2 by an inner wall 193. The aforementioned carry-in/out opening 191 is formed in the side surface of the processing vessel 190 in the transfer area T1. In addition, the inner wall 193 is also provided with a carry-in/out opening 194 for the upper wafer W1, the lower wafer W2, and the combined wafer T.

The inside of the processing vessel 190 is maintained constant at a preset humidity by a non-illustrated humidity maintaining mechanism. This allows the bonding apparatus 41 to perform a bonding process between the upper wafer W1 and the lower wafer W2 in a stable environment.

A transition device 200 for temporarily accommodating the upper wafer W1, the lower wafer W2, and the combined wafer T is provided on the negative Y-axis side of the transfer area T1. The transition device 200 is formed in, for example, two stages, and any two of the upper wafer W1, the lower wafer W2, and the combined wafer T can be simultaneously placed in the transition device 200.

A transfer mechanism 201 is provided in the transfer area T1. The transfer mechanism 201 has a transfer arm configured to be movable vertically, horizontally, and around a vertical axis. The transfer mechanism 201 is configured to transfer the upper wafer W1, the lower wafer W2, and the combined wafer T in the transfer area T1, or between the transfer area T1 and the processing area T2.

A position adjusting device 210 configured to adjust a direction of the horizontal direction in the upper wafer W1 and the lower wafer W2 is provided on the positive Y-axis side of the transfer area T1. In the position adjusting device 210, while rotating the upper wafer W1 and the lower wafer W2 attracted to and held by a non-illustrated holder, the positions of notches of the upper wafer W1 and the lower wafer W2 are detected by a non-illustrated detector.

In this way, the position adjusting mechanism 210 adjusts the positions of the notches to align the upper wafer W1 and the lower wafer W2 in the horizontal direction. In addition, an inverting device 220 configured to invert front and rear surfaces of the upper wafer W1 is provided in the transfer area T1. The inverting device 220 has a holding arm 221 for holding the upper wafer W1.

As shown in FIG. 6, an upper chuck 230 and a lower chuck 270 are provided in the processing area T2. The upper chuck 230 is configured to attract and hold the upper wafer W1 from above. The lower chuck 270 is located below the upper chuck 230, and is configured to attract and hold the lower wafer W2 from below. The upper chuck 230 is an example of a substrate holding device and a first holder, and the lower chuck 270 is an example of a second holder.

The upper chuck 230 is supported by a supporting member 300 provided on a ceiling surface of the processing vessel 190, as shown in FIG. 6. The supporting member 300 is equipped with a non-illustrated upper imaging device configured to image the bonding surface W2j of the lower wafer W2 held by the lower chuck 270. The upper imaging device is disposed adjacent to the upper chuck 230.

Further, as shown in FIG. 5 and FIG. 6, the lower chuck 270 is supported by a first lower chuck mover 310 that is provided below the lower chuck 270. The first lower chuck mover 310 moves the lower chuck 270 horizontally (in the Y-axis direction), as will be described later. The first lower chuck mover 310 is configured to be able to move the lower chuck 270 vertically and, also, to rotate it around a vertical axis.

As illustrated in FIG. 5, the first lower chuck mover 310 is equipped with a non-illustrated lower imaging device configured to image the bonding surface W1j of the upper wafer W1 held by the upper chuck 230. This lower imaging device is disposed adjacent to the lower chuck 270.

Further, as depicted in FIG. 5 and FIG. 6, the first lower chuck mover 310 is mounted to a pair of rails 315 that is provided on a bottom side of the first lower chuck mover 310 and extends in a horizontal direction (Y-axis direction). The first lower chuck mover 310 is configured to be movable along the rails 315.

The pair of rails 315 are provided on a second lower chuck mover 316. The second lower chuck mover 316 is mounted to a pair of rails 317 that is provided on a bottom side of the second lower chuck mover 316 and extends in a horizontal direction (X-axis direction).

The second lower chuck mover 316 is configured to be movable along the rails 317, that is, to move the lower chuck 270 in the horizontal direction (X-axis direction). The pair of rails 317 are provided on a placement table 318 that is disposed on a bottom surface of the processing container 190.

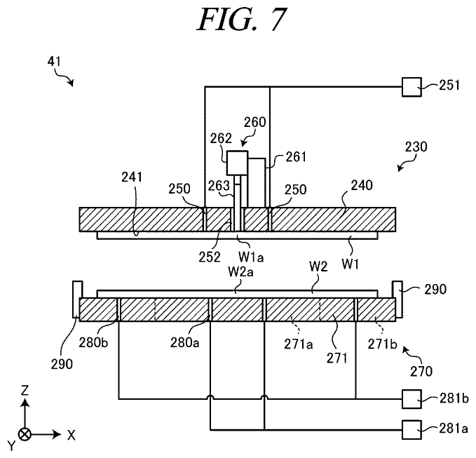

Now, a configuration of the upper chuck 230 and the lower chuck 270 in the bonding apparatus 41 will be explained with reference to FIG. 7. FIG. 7 is a schematic side view illustrating the configuration of the upper chuck 230 and the lower chuck 270 in the bonding apparatus 41 according to the exemplary embodiment.

The upper chuck 230 has a main body 240. The main body 240 is of a substantially circular plate shape, and has a circular attraction surface 241 facing the upper wafer W1. The main body 240 is provided with one or more suction holes 250. For example, the suction hole 250 is formed through the main body 240 in a thickness direction thereof.

One end of the suction hole 250 is located in a central region 241a (see FIG. 10) of the attraction surface 241. This one end of the suction hole 250 may be located at a position of, e.g., about 50 mm away from the center of the attraction surface 241.

A vacuum pump 251 is connected to the other end of the suction hole 250. The controller 5 (see FIG. 1) operates the vacuum pump 251 to attract and hold the upper wafer W1. A detailed configuration of the attraction surface 241 of the upper chuck 230 will be described later.

A through hole 252 is formed through a central portion of the upper chuck 230 in a thickness direction thereof. The central portion of the upper chuck 230 corresponds to a central portion W1a of the upper wafer W1 that is attracted to and held by the upper chuck 230. A pressing pin 263 of a substrate pressing device 260 is inserted through the through hole 252.

The substrate pressing device 260 is provided on a top surface of the upper chuck 230 and presses the central portion W1a of the upper wafer W1 with the pressing pin 263. The pressing pin 263 is configured to be movable linearly along a vertical axis by a cylinder member 261 and an actuator 262, and serves to press, with its leading end, a substrate (the upper wafer W1 in the present exemplary embodiment) facing it.

Specifically, the pressing pin 263 serves as a starter that first brings the central portion W1a of the upper wafer W1 and a central portion W2a of the lower wafer W2 into contact with each other when bonding the upper wafer W1 and the lower wafer W2 as will be described later.

The lower chuck 270 is of a substantially circular plate shape, and is divided into, a plurality of, e.g., two regions 271a and 271b. These regions 271a and 271b are arranged in this order from the center toward a periphery of the lower chuck 270. The region 271a has a circular shape when viewed from the top, and the region 271b has an annular shape when viewed from the top.

Suction holes 280a and 280b for attracting and holding the lower wafer W2 are independently provided in the regions 271a and 271b, respectively, as shown in FIG. 7. Separate vacuum pumps 281a and 281b are connected to the suction holes 280a and 280b, respectively. In this way, the lower chuck 270 is configured to be able to set the evacuation of the lower wafer W2 for each of the regions 271a and 271b.

Stopper members 290 are provided at multiple locations, for example, five locations around the periphery of the lower chuck 270 to suppress the upper wafer W1, the lower wafer W2, and the combined wafer T from sticking out of or slipping and falling off the lower chuck 270.

### <Processing Performed by Bonding System>

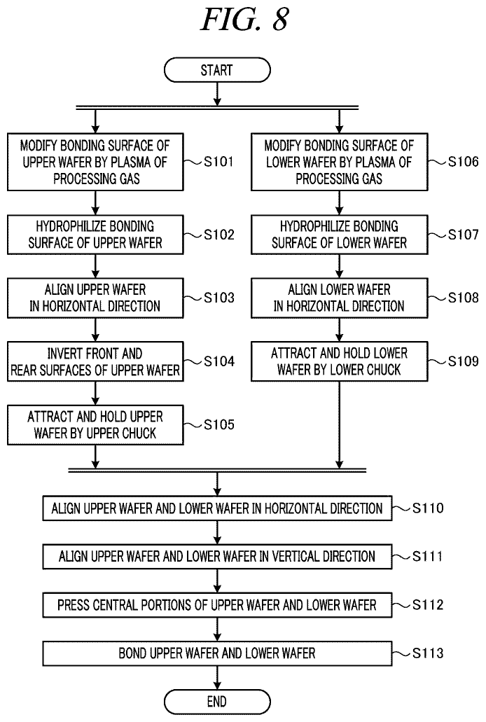

Subsequently, details of a processing performed by the bonding system 1 according to the exemplary embodiment will be explained with reference to FIG. 8. FIG. 8 is a flowchart showing a part of a processing sequence performed by the bonding system 1 according to the exemplary embodiment. The various processes shown in FIG. 8 are carried out under the control of the control device 4.

First, the cassette C1 accommodating the plurality of upper wafers W1, the cassette C2 accommodating the plurality of lower wafers W2, and the empty cassette C3 are respectively placed on the preset placement plates 11 of the carry-in/out station 2. Thereafter, the upper wafer W1 is taken out from the cassette C1 by the transfer device 22, and transferred to the transition device 50 of the third processing block G3 of the processing station 3.

Next, the upper wafer W1 is transferred to the surface modifying apparatus 30 of the first processing block G1 by the transfer device 61. At this time, as the gate valve 72 is open, the inside of the processing vessel 70 is open to the atmospheric pressure. In the surface modifying apparatus 30, a processing gas such as a nitrogen gas or a hydrogen gas is excited into plasma under a decompressed atmosphere to be ionized.

The ions thus generated are irradiated to the bonding surface W1j of the upper wafer W to plasma-process the bonding surface W1j. As a result, the bonding surface W1j of the upper wafer W1 is modified (process S101).

Subsequently, the upper wafer W1 is transferred by the transfer device 61 to the surface hydrophilizing apparatus 40 of the second processing block G2. In the surface hydrophilizing apparatus 40, while rotating the upper wafer W1 held by the spin huck, pure water is supplied onto the upper wafer W1.

As a result, the bonding surface W1j of the upper wafer W1 is hydrophilized (process S102). Also, the bonding surface W1j of the upper wafer W1 is cleaned by the pure water.

Next, the upper wafer W1 is transferred by the transfer device 61 to the bonding apparatus 41 of the second processing block G2. The upper wafer W1 carried into the bonding apparatus 41 is transferred to the position adjusting device 210 via the transition device 200. Then, alignment of the upper wafer W1 in the horizontal direction is carried out by the position adjusting device 210 (process S103).

Thereafter, the upper wafer W1 is transferred from the position adjusting device 210 to the inverting device 220. Subsequently, in the transfer area T1, the inverting device 220 is operated to turn the front and rear surfaces of the upper wafer W1 (process S104). That is, the bonding surface W1j of the upper wafer W1 is turned to face downwards.

Then, the inverting device 220 is pivoted and moved to below the upper chuck 230. Then, the upper wafer W1 is handed over from the inverting device 220 onto the upper chuck 230. The non-bonding surface W1n of the upper wafer W1 is attracted to and held by the upper chuck 230 (process S105).

While the above-described processes S101 to S105 are being performed on the upper wafer W1, the lower wafer W2 is also processed. First, the lower wafer W2 is taken out from the cassette C2 by the transfer device 22, and transferred to the transition device 50 of the processing station 3.

Next, the lower wafer W2 is transferred by the transfer device 61 to the surface modifying apparatus 30, where the bonding surface W2j of the lower wafer W2 is modified (process S106). This process S106 is the same as the above-described process S101.

Then, the lower wafer W2 is transferred by the transfer device 61 to the surface hydrophilizing apparatus 40, where the bonding surface W2j of the lower wafer W2 is hydrophilized (process S107). This process S107 is the same as the above-described process S102.

Thereafter, the lower wafer W2 is transferred by the transfer device 61 to the bonding apparatus 41. The lower wafer W2 carried into the bonding apparatus 41 is transferred to the position adjusting device 210 via the transition device 200. Then, the alignment of the lower wafer W2 in the horizontal direction is carried out by the position adjusting device 210 (process S108).

Subsequently, the lower wafer W2 is transferred to the lower chuck 270 to be attracted to and held by the lower chuck 270 (process S109). At this time, the non-bonding surface W2n of the lower wafer W2 is attracted to and held by the lower chuck 270 with the notch of the lower wafer W2 directed toward a preset direction.

Next, position alignment between the upper wafer W1 held on the upper chuck 230 and the lower wafer W2 held on the lower chuck 270 in the horizontal direction is performed (process S110).

Thereafter, the lower chuck 270 is moved vertically upwards by the first lower chuck mover 310 to adjust the positions of the upper chuck 230 and the lower chuck 270 in the vertical direction. As a result, the position alignment between the upper wafer W1 held on the upper chuck 230 and the lower wafer W2 held on the lower chuck 270 in the vertical direction is carried out (process S111).

At this time, a gap between the bonding surface W2j of the lower wafer W2 and the bonding surface W1j of the upper wafer W1 is set to a preset distance of, e.g., 80 μm to 200 μm.

Next, the pressing pin 263 of the substrate pressing device 260 is lowered to press down the central portion W1a of the upper wafer W1, thus pressing the central portion W1a of the upper wafer W1 and the central portion W2a of the lower wafer W2 with a preset force (process S112).

As a result, bonding starts between the pressed central portions W1a and W2a of the upper and lower wafers W1 and W2. Specifically, since the bonding surface W1j of the upper wafer W1 and the bonding surface W2j of the lower wafer W2 have been modified in the processes S101 and S106, respectively, a van der Waals force (intermolecular forces) is first generated between the bonding surfaces W1j and W2j, so that the bonding surfaces W1j and W2j are bonded to each other.

Furthermore, since the bonding surface W1j of the upper wafer W1 and the bonding surface W2j of the lower wafer W2 have been hydrophilized in the processes S102 and S107, respectively, OH groups between the bonding surfaces W1j and W2j form hydrogen bonds, so that the bonding surfaces W1j and W2j are firmly bonded to each other.

Thereafter, a bonding region between the upper wafer W1 and the lower wafer W2 expands from the central portions to peripheral portions of the upper and lower wafers W1 and W2. Then, while the central portion W1a of the upper wafer W1 and the central portion W2a of the lower wafer W2 are pressed by the pressing pin 263, the operation of the vacuum pump 251 is stopped, thereby stopping the evacuation of the upper wafer W1 through the suction holes 250.

As a result, the upper wafer W1 held on the attraction surface 241 falls onto the lower wafer W2. Then, the bonding between the bonding surfaces W1j and W2j due to the van der Waals force and the hydrogen bonds described above gradually expands from the central portions W1a and W2a toward the peripheral portions.

In this way, the entire bonding surface W1j of the upper wafer W1 come into contact with the entire bonding surface W2j of the lower wafer W2, so that the upper wafer W1 and the lower wafer W2 are bonded to each other (process S113).

Thereafter, the pressing pin 263 is raised up to the upper chuck 230. Also, the evacuation of the lower wafer W2 through the suction holes 280a and 280b is stopped in the lower chuck 270, so that the attracting and holding of the lower wafer W2 by the lower chuck 270 is released. This ends the bonding process in the bonding apparatus 41.

### <Configuration of Upper Chuck>

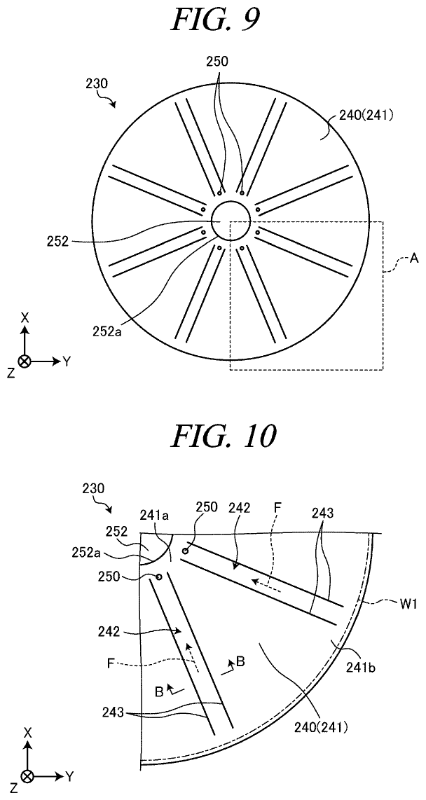

Now, a detailed configuration of the upper chuck 230 according to the exemplary embodiment will be explained with reference to FIG. 9 to FIG. 12. FIG. 9 is a plan view illustrating an example configuration of the upper chuck 230 according to the exemplary embodiment.

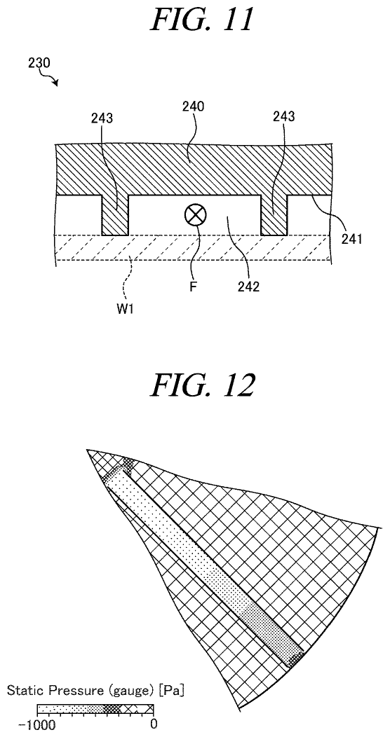

FIG. 10 is an enlarged plan view showing the example configuration of the upper chuck 230 according to the exemplary embodiment, and provides an enlarged view of a region A shown in FIG. 9. FIG. 11 is a cross sectional view taken along a line B-B of FIG. 10 in a direction indicated by the arrows.

As depicted in FIG. 9, the main body 240 of the upper chuck 230 has the circular attraction surface 241. Also, the upper chuck 230 has the one or more (eight in the shown example) suction holes 250 penetrating the main body 240 in the thickness direction and are exposed from the central region 241a (see FIG. 10) of the attraction surface 241.

The through hole 252 penetrating the upper chuck 230 in the thickness direction is formed in the central portion of the upper chuck 230. In addition, the attraction surface 241 is provided with an entire circumferential rib 252a located around the entire circumference of the through hole 252. This entire circumferential rib 252a is a wall portion that protrudes toward the upper wafer W1 facing the attraction surface 241.

As shown in FIG. 10, the attraction surface 241 has one or more (eight in the shown example) flow passages 242. The flow passage 242 is formed between each pair of ribs 243.

Each rib 243 extends in a straight line shape from the central region 241a of the attraction surface 241 to a peripheral region 241b of the attraction surface 241. The pair of ribs 243 forming one flow passage 242 are located substantially in parallel to each other on the attraction surface 241, for example.

As shown in FIG. 11, the rib 243 is a wall portion that protrudes toward the upper wafer W1 facing the attraction surface 241. For example, the rib 243 has the same height as the entire circumferential rib 252a.

In the exemplary embodiment, as depicted in FIG. 10, the suction hole 250 is located in each flow passage 242 near the central region 241a of the attraction surface 241.

In the present exemplary embodiment, as the vacuum pump 251 (see FIG. 7) is operated and the pair of ribs 243 come close to or into contact with the upper wafer W1, an air flow F that flows from the peripheral region 241b toward the suction hole 250 along the flow passage 242 is formed, as shown in FIG. 10 and FIG. 11.

This allows the flow velocity of the air flow F in the peripheral region 241b of the attraction surface 241 to become faster than when the flow passage 242 is not formed on the attraction surface 241. That is, in the exemplary embodiment, since the initial speed of the air flow F can be made faster, the attracting force for the upper wafer W1, which is proportional to the square of the flow velocity of the air flow F, can be increased in the entire attraction surface 241.

Therefore, according to the exemplary embodiment, the upper wafer W1 that has been warped can be stably held.

FIG. 12 shows a simulation result of the attracting force in the upper chuck 230 according to the exemplary embodiment. In this exemplary embodiment, since the flow velocity of the air flow F in the peripheral region 241b of the attraction surface 241 can be made faster, a negative pressure in the peripheral region 241b of the attraction surface 241 is found to be increased, as shown in FIG. 12.

Furthermore, in the exemplary embodiment, the entire upper wafer W1 may be attracted and held by the single vacuum pump 251, as shown in FIG. 7. Accordingly, it becomes unnecessary to suction the lower wafer W2 while sequentially controlling the multiple regions 271a and 271b as in the lower chuck 270, which eliminates the need for the equipment required for the sequential control.

Therefore, according to the exemplary embodiment, the manufacturing cost and the operating cost of the upper chuck 230 can be reduced. However, the present disclosure is not limited to the configuration where the upper chuck 230 attracts and holds the entire upper wafer W1 with only one vacuum pump 251, but it may also be possible to attract and hold the entire upper wafer W1 by sequentially controlling multiple vacuum pumps 251.

In addition, in the exemplary embodiment, as shown in FIG. 9, the multiple flow passages 242 (see FIG. 10) may be radially positioned on the attraction surface 241. This allows the entire upper wafer W1 to be attracted approximately evenly onto the attraction surface 241.

Therefore, according to the exemplary embodiment, the upper wafer W1 that has been warped can be held more stably.

Additionally, in the exemplary embodiment, the eight flow passages 242 may be arranged at an interval of 45° along the circumferential direction of the attraction surface 241. As for the semiconductor wafer such as the upper wafer W1, its various types of physical properties change at the interval of 45°. By providing the flow passages 242 to correspond to this periodic change in the physical properties, it is possible to suppress the upper wafer W1 from being damaged during the attraction due to the periodic change in the physical properties.

Therefore, according to the exemplary embodiment, the warped upper wafer W1 can be held more stably.

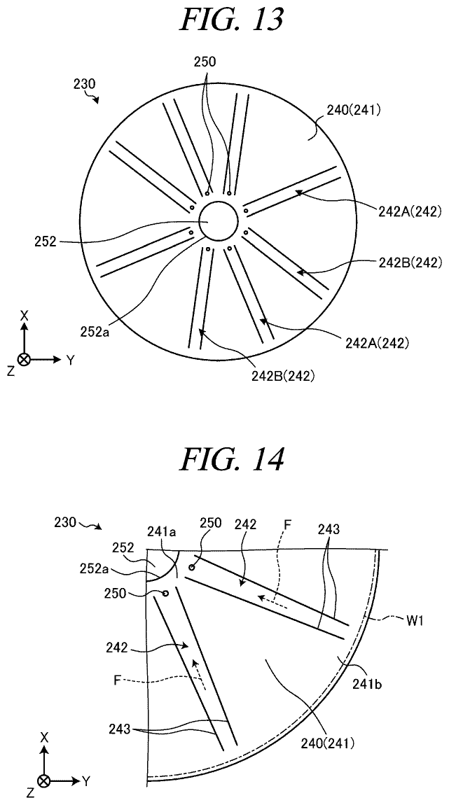

Further, although the above exemplary embodiment has been described for the example where the eight flow passages 242 are arranged at the interval of 45° along the circumferential direction of the attraction surface 241, the present disclosure is not limited thereto. FIG. 13 is a plan view illustrating another example configuration of the upper chuck 230 according to the exemplary embodiment.

As illustrated in FIG. 13, in the present disclosure, four flow passages 242A among the eight flow passages 242 may be arranged at an interval of 90° along the circumferential direction of the attraction surface 241, and the remaining four flow passages 242B may be positioned at two different angular intervals with respect to the adjacent flow passages 242A. These two different angles are, for example, 30° and 60°.

With this configuration, when the upper wafer W1 is warped in a saddle shape, four portions of the upper wafer W1 close to the attraction surface 241 can be efficiently suctioned, using the four flow passages 242B.

Further, when attracting the upper wafer W1 warped in the saddle shape, the suction force from the suction hole 250 may be turned on/off, or strengthened or weakened depending on the state of the warpage of the upper wafer W1. This allows the upper wafer W1 warped in the saddle shape to be more efficiently attracted.

In addition, when attracting the upper wafer W1 warped in the saddle shape, the controller 5 (see FIG. 1) may measure the warpage of the upper wafer W1 by using a warpage measuring device provided separately inside or outside the bonding system 1 (see FIG. 1), and then may attract the upper wafer W1 with the upper chuck 230. This allows the upper wafer W1 warped in the saddle shape to be stably attracted.

Furthermore, when attracting the upper wafer W1 warped in the saddle shape, the controller 5 may perform the attraction process for the upper wafer W1 while monitoring the pressure of each flow passage 242 by using multiple pressure gauges (not shown) capable of measuring the internal pressure of the respective flow passages 242.

By way of example, the controller 5 may enhance the suction force from the corresponding suction hole 250 for the flow passage 242 having a low pressure. Also, the controller 5 may store the suction force that has caused a pressure increase, and when attracting the next upper wafer W1, an attracting process for the next upper wafer W1 may be performed with this stored suction force. This allows the upper wafer W1 warped in the saddle shape to be attracted more efficiently.

Additionally, in the exemplary embodiment, the upper wafer W1 may be held on the attraction surface 241 so that the notch portion formed at the upper wafer W1 avoids the flow passages 242. By way of example, in the example of FIG. 9, the upper wafer W1 may be held on the attraction surface 241 so that the notch portion of the upper wafer W1 is located at the three o'clock position of the attraction surface 241.

This makes it possible to suppress the upper wafer W1 from being damaged due to the periodic change in the physical properties of the upper wafer W1 when the upper wafer W1 is attracted. Therefore, according to the exemplary embodiment, the warped upper wafer W1 can be held more stably.

Furthermore, in the exemplary embodiment, the attraction surface 241 of the upper chuck 230 may have the entire circumferential rib 252a located around the entire circumference of the through hole 252. This configuration makes it possible to suppress the suction force from the suction hole 250 from leaking through the through hole 252, thereby enabling a further increase of the flow velocity of the air flow F in the peripheral region 241b of the attraction surface 241.

Therefore, according to the exemplary embodiment, the attracting force for the upper wafer W1 can be further increased in the entire attraction surface 241, so that the warped upper wafer W1 can be held more stably.

### First and Second Modification Examples

Subsequently, various modification examples of the exemplary embodiment will be explained with reference to FIG. 14 to FIG. 21. In the following various modification examples, the same parts as in the exemplary embodiments will be assigned the same reference numerals, and redundant descriptions thereof will be omitted.

FIG. 14 is an enlarged plan view illustrating an example configuration of the upper chuck 230 according to a first modification example of the exemplary embodiment, which corresponds to FIG. 10 of the exemplary embodiment. As depicted in FIG. 14, in the first modification example, the positional relationship between the ribs 243 belonging to one flow passage 242 is different from that in the above-descried exemplary embodiment.

Specifically, in the first modification example, the ribs 243 are not positioned in parallel to each other on the attraction surface 241, but are positioned inclined with respect to each other. Also, in the first modification example, the width of the flow passage 242 in the peripheral region 241b is smaller than the width of the flow passage 242 in the central region 241a.

With this configuration, the cross sectional area of the flow passage 242 in the peripheral region 241b can be made smaller than the cross sectional area of the flow passage 242 in the central region 241a, so that the flow velocity of the air flow F in the peripheral region 241b of the attraction surface 241 can be made faster.

Therefore, according to the first modification example, since the attracting force for the upper wafer W1 can be further increased in the entire attraction surface 241, the warped upper wafer W1 can be held more stably.

In the present disclosure, the method of reducing the cross sectional area of the flow passage 242 in the peripheral region 241b is not limited to reducing the width of the flow passage 242 in the peripheral region 241b.

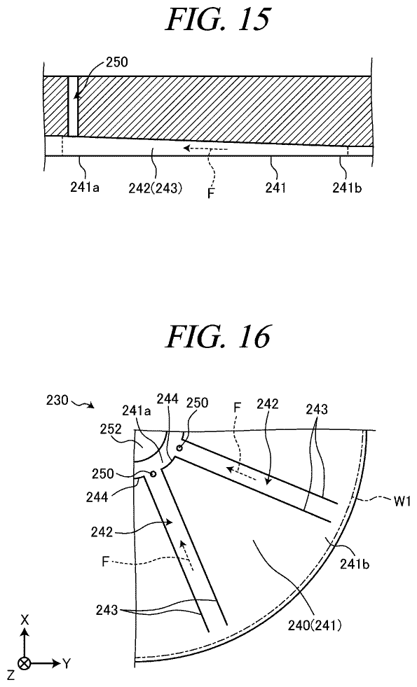

FIG. 15 is a cross sectional view illustrating an example configuration of the upper chuck 230 according to a second modification example. As illustrated in FIG. 15, in the second modification example, the height of the flow passage 242 in the peripheral region 241b is smaller than the height of the flow passage 242 in the central region 241a.

This also makes it possible to set the cross sectional area of the flow passage 242 in the peripheral region 241b to be smaller than the area of the flow passage 242 in the central region 241a, so that the flow velocity of the air flow F in the peripheral region 241b of the attraction surface 241 can be further increased.

Therefore, according to the second modification example, the attracting force for the upper wafer W1 can be further increased in the entire attraction surface 241, so that the warped upper wafer W1 can be held more stably.

### Third Modification Example

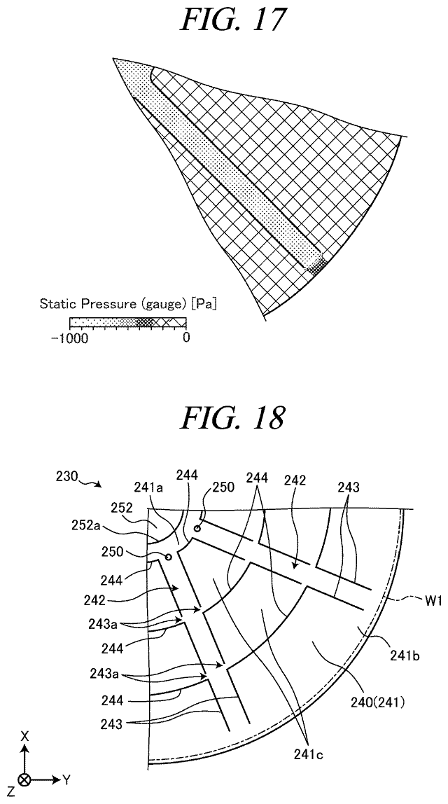

FIG. 16 is an enlarged plan view illustrating an example configuration of the upper chuck 230 according to a third modification example of the exemplary embodiment, which corresponds to FIG. 10 of the exemplary embodiment. FIG. 17 shows a simulation result of the attracting force in the upper chuck 230 according to the third modification example of the exemplary embodiment.

As shown in FIG. 16, in the third modification example, the configuration of the central region 241a of the attraction surface 241 is different from that of the above-described exemplary embodiment. Specifically, in the third modification example, multiple arc ribs 244 are provided in the central region 241a of the attraction surface 241.

The arc rib 244 connects the mutually adjacent ribs 243 that respectively belong to the different flow passages 242 adjacent to each other. For example, in the example of FIG. 16, ends of the mutually adjacent ribs 243 on the central region 241a side are connected by the arc rib 244.

The arc rib 244 extends in an arc shape along the circumferential direction of the attraction surface 241. The arc rib 244 is a wall portion that protrudes toward the upper wafer W1 facing the attraction surface 241. The arc rib 244 has, for example, the same height as the rib 243.

By providing the multiple arc ribs 244, the multiple suction holes 250 are connected to a circular ring-shaped region surrounded by the entire circumferential rib 252a and the multiple arc ribs 244, so that the central region 241a of the attraction surface 241 can be more efficiently decompressed through the multiple suction holes 250, as shown in FIG. 17.

Therefore, in the third modification example, the flow velocity of the air flow Fin the flow passage 242 and the peripheral region 241b can be further increased. Thus, according to the third modification example, the attraction force for the upper wafer W1 can be further increased across the entire attraction surface 241, so that the warped upper wafer W1 can be more stably held.

In the third modification example, the arc ribs 244 may be located in the central region 241a of the attraction surface 241. This reduces the area of the annular region formed by the entire circumferential rib 252a and the multiple arc ribs 244, so that the central region 241a of the attraction surface 241 can be more efficiently suctioned by the multiple suction holes 250.

Therefore, in the third modification example, the flow rate of the air flow F in the flow passage 242 and the peripheral region 241b can be further increased. Therefore, according to the third modification example, the attracting force of the upper wafer W1 can be further increased over the entire attraction surface 241, so that the warped upper wafer W1 can be more stably held.

### Fourth and Fifth Modification Examples

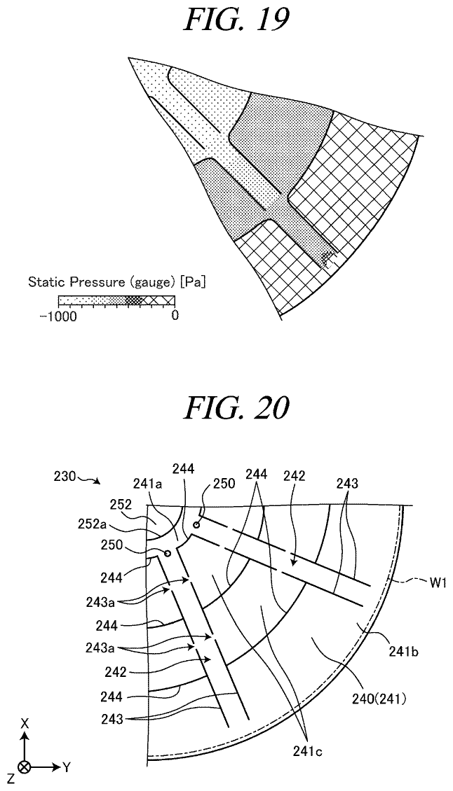

FIG. 18 is an enlarged plan view illustrating an example configuration of the upper chuck 230 according to a fourth modification example, which corresponds to FIG. 10 of the exemplary embodiment. FIG. 19 is a diagram showing a simulation result of the attracting force in the upper chuck 230 according to the fourth modification example.

As shown in FIG. 18, in the fourth modification example, the configuration between the central region 241a and the peripheral region 241b of the attraction surface 241 is different from that of the third modification example described above. Specifically, in the fourth modification example, the arc ribs 244 are located not only in the central region 241a of the attraction surface 241, but also in a region between the central region 241a and the peripheral region 241b of the attraction surface 241.

In the fourth modification example, the rib 243 may have a groove portion 243a that connect an inner region 241c, which is surrounded by a plurality of ribs 243 including the corresponding rib 243 and a plurality of arc ribs 244, to the flow passage 242.

With this configuration, the inner regions 241c located between the adjacent flow passages 242 can be suctioned through the flow passages 242, so that these inner regions 241c can also be efficiently decompressed, as illustrated in FIG. 19.

Therefore, according to the fourth modification example, since the attracting force for the upper wafer W1 can be further increased in the entire attraction surface 241, the warped upper wafer W1 can be held more stably.

Furthermore, in the fourth modification example, the groove portion 243a may be located on the upstream side of the flow passage 242 at a boundary portion between the flow passage 242 and the inner region 241c (that is, at an outer peripheral side of the boundary portion). With this configuration, a pressure loss between the suction hole 250 and the inner region 241c is increased, so that a decrease in the flow velocity of the air flow F (see FIG. 10) that might be caused by connecting the flow passage 242 and the inner region 241c can be suppressed.

Therefore, according to the fourth modification example, the attracting force for the upper wafer W1 can be well maintained, so that the warped upper wafer W1 can be stably held.

Further, in the present disclosure, the position of the groove portions 243a is not limited to the example of FIG. 18. FIG. 20 is an enlarged cross sectional view illustrating an example configuration of the upper chuck 230 according to a fifth modification example.

As shown in FIG. 20, the groove portion 243a of the present disclosure may be located at a position other than the upstream side of the flow passage 242 at the boundary between the flow passage 242 and the inner region 241c. By way of example, the groove portion 243a may be located at a central portion of the boundary between the flow passage 242 and the inner region 241c.

This also allows the inner regions 241c located between the neighboring flow passages 242 to be suctioned through the flow passages 242, so that the inner regions 241c can also be efficiently decompressed. According to the fifth modification example, since the attracting force for the upper wafer W1 can be further increased in the entire attraction surface 241, the warped upper wafer W1 can be held more stably.

In addition, in the fourth and fifth modification examples, the arc rib 244 may be provided with a suction hole (not shown) for detecting whether the upper wafer W1 is in contact with the arc rib 244. This enables accurate determination on the position of the attraction surface 241 up to which the upper wafer W1 is in contact when the upper wafer W1 is attracted to the upper chuck 230.

Also, in the fourth and fifth modification examples, the inner region 241c may be provided with holes (not shown) for arranging various sensors.

### Sixth Modification Example

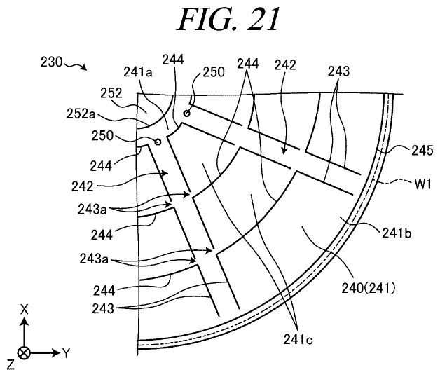

FIG. 21 is an enlarged plan view illustrating an example configuration of the upper chuck 230 according to a sixth exemplary embodiment, which corresponds to FIG. 10 of the exemplary embodiment.

As shown in FIG. 21, in the sixth modification example, the configuration of the peripheral region 241b of the attraction surface 241 is different from that of the fourth modification example. Specifically, in the sixth modification example, the attraction surface 241 of the upper chuck 230 may further have a circumferential rib 245 located at an outer side than the ribs 243 and extending along the entire circumference of the attraction surface 241.

With this configuration, it is possible to suppress the negative pressure between the upper wafer W1 and the attraction surface 241 from leaking out from the outer side of the attraction surface 241 after the entire upper wafer W1 is held by the upper chuck 230. Therefore, according to the sixth modification example, the upper wafer W1 can be held more stably.

A substrate holding device (upper chuck 230) according to the exemplary embodiment includes the main body 240, the flow passage 242, and the suction hole 250. The main body 240 has the circular attraction surface 241 facing the circular plate-shaped substrate (upper wafer W1). The flow passage 242 is formed between the pair of ribs 243 extending from the central region 241a of the attraction surface 241 to the peripheral region 241b of the attraction surface 241. The suction hole 250 is located on the central region 241a side of the attraction surface 241 in the flow passage 242. In addition, as the pair of ribs 243 come close to or into contact with the substrate (upper wafer W1), the air flow F is formed along the flow passage 242, heading from the peripheral region 241b toward the suction hole 250. This allows the warped upper wafer W1 to be stably held.

In addition, in the substrate holding device (upper chuck 230) according to the exemplary embodiment, the flow passage 242 is plural in number. The mutually adjacent ribs 243 respectively belonging to the different flow passages 242 adjacent to each other are connected by the arc rib 244 that extends along the circumferential direction of the attraction surface 241. This makes it possible to hold the warped upper wafer W1 more stably.

Furthermore, in the substrate holding device (upper chuck 230) according to the exemplary embodiment, the arc rib 244 is located in the central region 241a of the attraction surface 241. This makes it possible to hold the warped upper wafer W1 more stably.

In addition, in the substrate holding device (upper chuck 230) according to the exemplary embodiment, the arc rib 244 is also located in the region between the central region 241a of the attraction surface 241 and the peripheral region 241b of the attraction surface 241. Also, the rib 243 has the groove portion 243a that connects the inner region 241c, which is surrounded by the multiple ribs 243 and the multiple arc ribs 244, to the flow passage 242. This allows the warped upper wafer W1 to be held more stably.

Additionally, in the substrate holding device (upper chuck 230) according to the exemplary embodiment, the flow passage 242 is plural in number. The multiple flow passages 242 are located radially on the attraction surface 241. This allows the warped upper wafer W1 to be held more stably.

Furthermore, in the substrate holding device (upper chuck 230) according to the exemplary embodiment, the multiple flow passages 242 are evenly arranged along the circumferential direction of the attraction surface 241. This allows the upper wafer W1, which has undergone warping, to be held more stably.

Furthermore, in the substrate holding device (upper chuck 230) according to the exemplary embodiment, the number of the flow passages 242 is eight. These eight flow passages 242 are arranged at the interval of 45° along the circumferential direction of the attraction surface 241. This allows the upper wafer W1, which has undergone warping, to be held more stably.

Furthermore, in the substrate holding device (upper chuck 230) according to the exemplary embodiment, the substrate (upper wafer W1) is held on the attraction surface 241 so that the notch of the substrate (upper wafer W1) avoids the flow passages 242. This allows the warped upper wafer W1 to be held more stably.

Moreover, the substrate holding device (upper chuck 230) according to the exemplary embodiment further includes the circumferential rib 245 that is located along the entire circumference of the attraction surface 241 at the outer side than the multiple ribs 243. This allows the upper wafer W1 to be held more stably.

The bonding system 1 according to the exemplary embodiment further includes the surface modifying apparatus 30, the surface hydrophilizing apparatus 40, and the bonding apparatus 41. The surface modifying apparatus 30 modifies the surface (bonding surface W1j) of the first substrate (upper wafer W1) and the surface (bonding surface W2j) of the second substrate (lower wafer W2). The surface hydrophilizing apparatus 40 hydrophilizes the modified surfaces (bonding surfaces W1j and W2j) of the first and second substrates (upper and lower wafers W1 and W2). The bonding apparatus 41 bonds the hydrophilized first and second substrates (upper wafer and lower wafers W1 and W2) by the intermolecular force. The bonding apparatus 41 also has the first holder (upper chuck 230) and the second holder (lower chuck 270). The first holder (upper chuck 230) attracts and holds the first substrate (upper wafer W1) from above. The second holder (lower chuck 270) is located below the first holder (upper chuck 230), and attracts and holds the second substrate (lower wafer W2) from below. The first holder (upper chuck 230) is equipped with the main body 240, the flow passage 242, and the suction hole 250. The main body 240 has the circular attraction surface 241 facing the circular plate-shaped substrate (upper wafer W1). The flow passage 242 is formed between the pair of ribs 243 that extend from the central region 241a of the attraction surface 241 to the peripheral region 241b of the attraction surface 241. The suction hole 250 is located on the central region 241a side of the attraction surface 241 in the flow passage 242. In addition, as the pair of ribs 243 come close to or into contact with the substrate (upper wafer W1), the air flow F is formed along the flow passage 242, heading from the peripheral region 241b toward the suction hole 250. With this configuration, the upper wafer W1 having undergone warping can be stably held.

So far, the exemplary embodiment of the present disclosure has been described. However, the present disclosure is not limited to the above-described exemplary embodiment, and various changes and modifications may be made without departing from the spirit of the present disclosure.

It should be noted that the exemplary embodiment disclosed herein is illustrative in all aspects and is not anyway limiting. In fact, the above-described exemplary embodiment may be embodied in various forms. The above-described exemplary embodiment may be omitted, replaced and modified in various ways without departing from the scope and the spirit of claims.

According to the exemplary embodiment, it is possible to stably hold the substrate that has undergone warping.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate holding device, comprising:
a main body having a circular attraction surface facing a circular plate-shaped substrate; and
a flow passage formed between a pair of ribs extending from a central region of the attraction surface to a peripheral region of the attraction surface, the flow passage including a suction hole on a central region side of the attraction surface,
wherein the suction hole is configured to cause air flow along the flow passage from the peripheral region toward the suction hole in response to the pair of ribs coming close to or into contact with the substrate.

2. The substrate holding device of claim 1,
wherein the at least one flow passage includes a plurality of flow passages, and
adjacent ribs belonging to different flow passages among the plurality of flow passages are connected by an arc rib that extends along a circumferential direction of the attraction surface.

3. The substrate holding device of claim 2,
wherein each arc rib is located in the central region of the attraction surface.

4. The substrate holding device of claim 3,
wherein each arc rib is also located in a region between the central region of the attraction surface and the peripheral region of the attraction surface, and
each rib has a at least one groove portion that connects an inner region to the flow passage, the inner region being surrounded by a rib of an adjacent one of the flow passages and a plurality of the arc ribs.

5. The substrate holding device of claim 1,
wherein at least one flow passage includes a plurality of flow passages, and
the plurality of flow passages are radially located on the attraction surface.

6. The substrate holding device of claim 5,
wherein the plurality of flow passages are evenly arranged along a circumferential direction of the attraction surface.

7. The substrate holding device of claim 6,
wherein a number of the plurality of flow passages is eight, and
the plurality of flow passages are arranged at an interval of 45° along the circumferential direction of the attraction surface.

8. The substrate holding device of claim 1,
wherein the substrate is to be held by the attraction surface such that a notch of the substrate avoids the flow passage.

9. The substrate holding device of claim 1, further comprising:
an entire circumferential rib extending along an entire circumference of the attraction surface.

10. The substrate holding device of claim 1, further comprising:
a through hole in a central portion of the substrate holding device, the through hole positioned radially inward of the pair of ribs of the at least one flow passage,
wherein the through hole is configured to receive a pressing pin of a substrate pressing device.

11. A bonding system, comprising:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates by an intermolecular force,
wherein the bonding apparatus comprises:
a first holder configured to attract and hold the first substrate from above; and
a second holder located below the first holder, and configured to attract and hold the second substrate from below,
the first holder comprises:
a main body having a circular attraction surface facing a circular plate-shaped substrate; and
a flow passage formed between a pair of ribs extending from a central region of the attraction surface to a peripheral region of the attraction surface, the flow passage including a suction hole located on a central region side of the attraction surface, and
the suction hole is configured to cause air flow along the flow passage from the peripheral region toward the suction hole in response to the pair of ribs coming close to or into contact with the substrate.

12. The bonding system of claim 11,
wherein the at least one flow passage includes a plurality of flow passages, and
adjacent ribs belonging to different flow passages are connected by an arc rib that extends along a circumferential direction of the attraction surface.

13. The bonding system of claim 12,
wherein each arc rib is located in the central region of the attraction surface.

14. The bonding system of claim 13,
wherein each arc rib is also located in a region between the central region of the attraction surface and the peripheral region of the attraction surface, and
each rib has a at least one groove portion that connects an inner region to the flow passage, the inner region being surrounded by a rib of an adjacent one of the flow passages and a plurality of the arc ribs.

15. The bonding system of claim 11,
wherein at least one flow passage includes a plurality of flow passages, and
the plurality of flow passages are radially located on the attraction surface.

16. The bonding system of claim 15,
wherein the plurality of flow passages are evenly arranged along a circumferential direction of the attraction surface.

17. The bonding system of claim 16,
wherein a number of the plurality of flow passages is eight, and
the plurality of flow passages are arranged at an interval of 45° along the circumferential direction of the attraction surface.

18. The bonding system of claim 11,
wherein the substrate is to be held by the attraction surface such that a notch of the substrate avoids the flow passage.

19. The bonding system of claim 11, further comprising:
an entire circumferential rib extending along an entire circumference of the attraction surface.

20. The bonding system of claim 11, further comprising:
a through hole in a central portion of the substrate holding device, the through hole positioned radially inward of the pair of ribs of the at least one flow passage,
wherein the through hole is configured to receive a pressing pin of a substrate pressing device.
